(19) United States
(12) Patent Application Publication
(10) Pub. No.: US 2026/0201969 A1
(43) Pub. Date: Jul. 16, 2026

(54) LIQUID COOLING AUTOMATIC DISCONNECT COMPONENT

(71) Applicant: DELL PRODUCTS L.P., Round Rock, TX (US)

(72) Inventors: Kevin Mundt, Livingston, TX (US); James Utz, Georgetown, TX (US)

(21) Appl. No.: 19/022,089

(22) Filed: Jan. 15, 2025

(51) Int. Cl. F16K 15/02; H05K 7/20

(52) U.S. Cl. CPC F16K 15/026; H05K 7/20272; H05K 7/20781

(57) ABSTRACT

An inline check valve of an information handling system includes a housing, a check valve seat, and a compression bladder. The housing enables a cooling liquid to flow in first and second directions through the inline check valve. The check valve seat is located within the housing and enables the cooling liquid to flow only in the first direction through the housing. The check valve seat is biased toward a first end of the housing. The compression bladder is located within the housing and collapses to enable fluid displacement within the housing.

### FIELD OF THE DISCLOSURE

The present disclosure generally relates to information handling systems, and more particularly relates to a liquid cooling automatic disconnect component.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An inline check valve of an information handling system includes a housing, a check valve seat, and a compression bladder. The housing may enable a cooling liquid to flow in first and second directions through the inline check valve. The check valve seat is located within the housing and may enable the cooling liquid to flow only in the first direction through the housing. The check valve seat may be biased toward a first end of the housing. The compression bladder is located within the housing and may collapse to enable fluid displacement within the housing.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of a system including multiple information handling systems according to at least one embodiment of the present disclosure;

FIG. 2 is an exploded perspective view of an inline check valve according to at least one embodiment of the present disclosure;

FIG. 3 is a perspective view of an inline check valve with internal components of the main housing visible according to at least one embodiment of the present disclosure;

FIG. 4 is a cross-sectional view of an inline check valve according to at least one embodiment of the present disclosure;

FIG. 5 is a perspective view of a check valve seat and a compression bladder for an inline check valve according to at least one embodiment of the present disclosure;

FIG. 6 is a perspective view of a compression bladder for an inline check valve according to at least one embodiment of the present disclosure; and

FIG. 7 is a block diagram of a general information handling system according to at least one embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

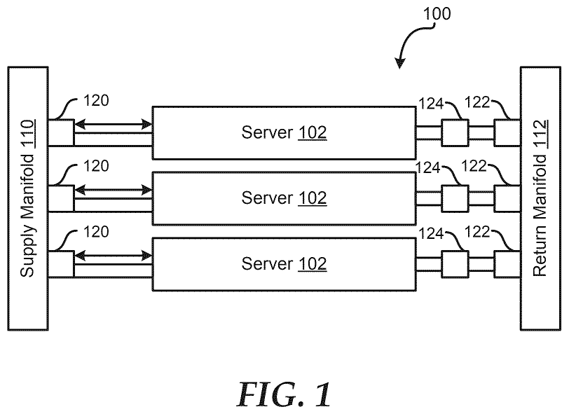

FIG. 1 illustrates a system 100 including multiple information handling systems 102 according to at least one embodiment of the present disclosure. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various other I/O devices, such as a keyboard, a mouse, and a video display. The information handling system may also include one or more busses operable to transmit communications between the various hardware components.

System 100 further includes a supply manifold 110, a return manifold 112, multiple quick disconnect components 120, multiple return side connectors 122, and multiple inline check valves 124. System 100 may be any suitable system, such as an information handling system or server rack. Supply manifold 110 may provide cold cooling liquid to each information handling system or server 102 in the larger information handling system or server rack. Return manifold 112 may receive hot cooling liquid from each information handling system or server 102 in the larger information handling system or server rack. A different one of quick disconnect components 120 may be connected between supply manifold 110 and a different liquid cooling supply line. Similarly, a different one of return side connectors 122 may be connected between return manifold 112 and a different liquid cooling return line. In certain examples, a different one of quick disconnect components 120 may be electrically coupled to a different corresponding server 102. System 100 may include additional components without varying from the scope of this disclosure.

In an example, supply manifold 110, return manifold 112, multiple quick disconnect components 120, multiple return side connectors 122, and multiple inline check valves 124 may form a portion of a direct liquid cooling for information handling systems or servers 102. The direct liquid cooling system may also include one or more cold plates in each of the servers 102, a main supply liquid system connected to supply manifold 110, and a main return liquid line connected to return manifold 112. In an example, return side connectors 122 may not be included within system 100. In this example, inline check valves 124 may connect direct to return manifold 112.

In certain situations, a leak may occur at one or more of the components of the liquid cooling system within system 100, which may cause damage to information handling systems 102. In an example, both supply manifold 120 and return manifold 122 are pressurized, such that if the flow of cooling liquid is not stopped the pressurized cooling liquid may continue to flow at the source of the leak. For example, a leak in a cooling loop of server 102 would be fed from both the cold line of supply manifold 110 and the hot return line connected to return manifold 112. Thus, both connections to supply and return manifolds 110 and 112 need to be isolated. Quick disconnect components 120 and inline check valves 124 may be utilized to mitigate a leak within system 100. For example, in response to a detected leak, quick disconnect components 120 may shut off the flow of cooling liquid from supply manifold 110 to server 102 in which the leak was detected. Additionally, inline check valves 124 may prevent a backflow of cooling liquid from return manifold 112.

In an example, inline check valves 124 allow for flow in only one direction and may be oriented so that the cooling liquid may flow to hot return manifold 112 but can't backflow in the case of a leak. When a leak is detected, server 102 may assert quick disconnect component 120 and the flow will cease from cold supply manifold 110. The check valve 122 may prevent backflow from hot return manifold 122. Based on these operations, the server cooling loop is now isolated from the pressure of both manifolds 120 and 122.

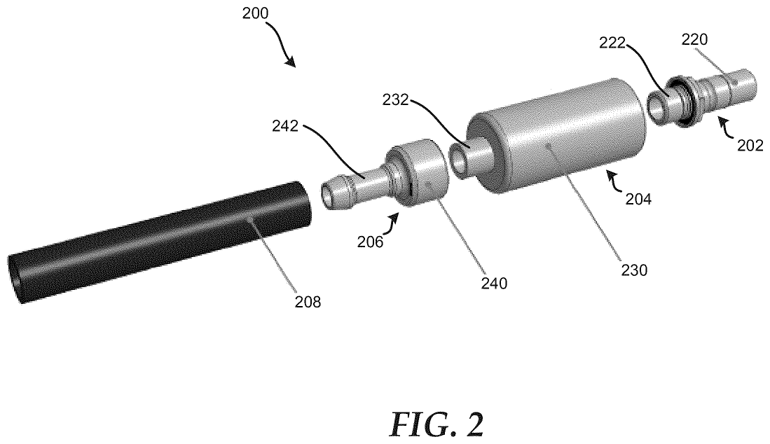

FIG. 2 illustrates an inline check valve 200 according to at least one embodiment of the present disclosure. Inline check valve 200 may be substantially similar to inline check valves 124 of FIG. 1. Inline check valve 200 includes a quick disconnect plug 202, a pressure relieving check valve 204, a hose barb fitting 206, and a hose 208. Quick disconnect plug 202 includes a attachment portion 220 and a snap portion 222. Pressure relieving check valve 204 includes a housing 230 and an insert portion 232. Hose barb fitting 206 includes a slip joint 240 and a barb portion 242. In an example, inline check valve 200 may be a combination of both a quick disconnect component and a check valve component. Inline check valve 200 may include additional components without varying from the scope of this disclosure.

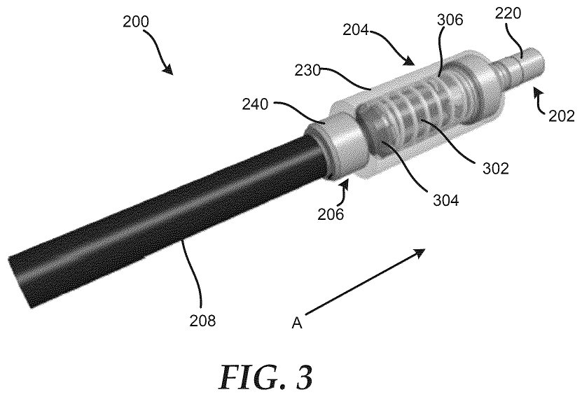

In an example, attachment portion 220 of quick disconnect plug 202 may connect to or be inserted within a hose extending from a return manifold, such as return manifold 112 of FIG. 1, or may connect directly to the return manifold. Snap portion 222 of quick disconnect plug 202 may snap fit within housing 230 of pressure relieving check valve 204. Insert portion 232 of pressure relieving check valve 204 may be inserted within slip joint 240 of hose barb fitting 206. Barb portion 242 of hose barb fitting 206 may be inserted and secured within hose 208. In an example, hose 208 may be connected to a server, such as server 102 of FIG. 1. These connections of inline check valve 200 are illustrated in FIG. 3.

FIG. 3 illustrates inline check valve 200 with a portion of housing 230 shown as transparent according to at least one embodiment of the present disclosure. In an example, housing 230 may be a rigid metal assembly, such that the housing may sustain a particular amount of pressure increase without rupturing or leaking cooling liquid. Pressure relieving check valve 204 includes a compression bladder 302, a check valve seat 304, and a spring 306. Pressure relieving check valve 204 may include additional components without varying from the scope of this disclosure.

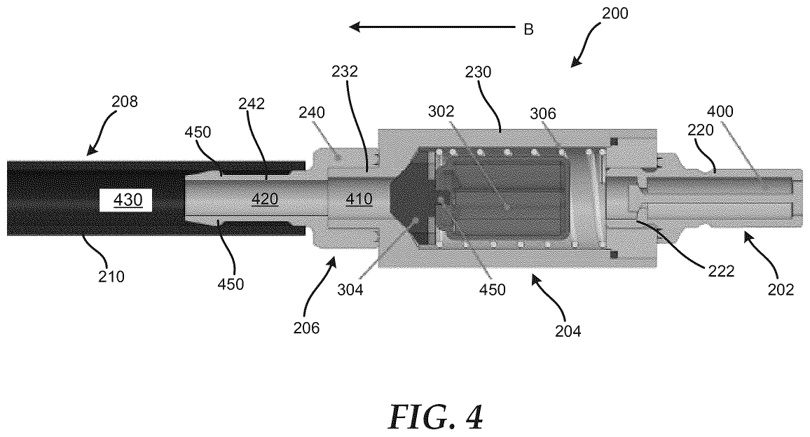

In an example, the cooling liquid may flow into pressure relieving check valve 204 in the direction of arrow A. The flow of the cooling liquid in the direction of arrow A may enter pressure relieving check valve 204 through the opening, such as opening 410 of FIG. 4, of the check valve adjacent to slip joint 240. As the cooling liquid flows into pressure relieving check valve 204, the force exerted by the cooling liquid flow on check valve seat 304 may exceed the force exerted by spring 306 on the check valve seat. In this situation, check valve seat 304 may be pushed away from the opening of pressure relieving check valve 204 adjacent to slip joint 240. When the flow of the cooling liquid stops, the force exerted by spring 306 on check valve seat 304 may bias check valve seat 304 toward the opening of pressure relieving check valve 204 adjacent to slip joint 240 as illustrated in FIG. 4.

FIG. 4 is a cross-sectional view of inline check valve 200 according to at least one embodiment of the present disclosure. Insert portion 232 includes an opening 410. Hose barb fitting 206 includes an opening 420. Hose 208 includes a channel 430. Hose barb fitting 206 includes barbs 450 located at an end of a shaft of barb portion 242. In an example, barbs 450 may be on the opposite end of the shaft as compared to slip joint 240. In certain examples, barbs 450 may securely hold barb portion 242 of hose barb fitting 206 within channel 430 of hose 208.

Inline check valve 200 includes quick disconnect plug 202, pressure relieving check valve 204, hose barb fitting 206, and hose 208. Quick disconnect plug 202 includes attachment portion 220 and snap portion 222. Pressure relieving check valve 204 includes housing 230 and insert portion 232. Hose barb fitting 206 includes slip joint 240 and barb portion 242. In an example, inline check valve 200 may be a combination of both a quick disconnect component and a check valve component. Inline check valve 200 may include additional components without varying from the scope of this disclosure.

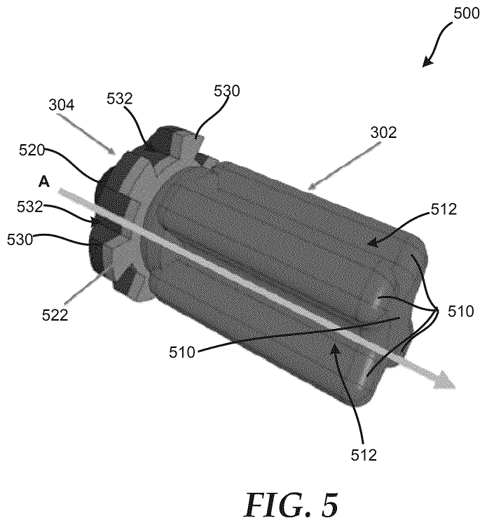

In an example, check valve seat 304 may be formed from any suitable material to enable the check valve to form a seal at opening 410. For example, check valve seat 304 may be a rubber seal that may compress and stop a back flow of the cooling liquid from housing 230 into hose 208 in the direction of arrow B. In certain examples, spring 306 may exert a force on check valve seat 304 to bias the check valve seat in physical communication or in contact with opening 410. In an example, compression bladder 302 may be attached to check valve seat 304 via a tab 450. Compression bladder 302 may be an air-filled bladder that can compress to enable fluid displacement within housing 230. In certain examples, when coolant is flowing in a normal direction, such as in the direction of arrow A in FIGS. 3 and 5, a force exerted on check valve seat 304 may overcome or be greater than the force of spring 306. In this situation, check valve seat 304 may be in an open position within housing 230 of pressure relieving check valve 204.

In response to a cooling liquid leak, the cooling liquid may stop flowing and quick disconnect plug 202 may release from a return side connector of a liquid cooling assembly, such as return side connector 122 of system 100. This disconnection may result in the cooling liquid no longer being able to exit housing 230 of inline check valve 200, such that an increased amount of cooling liquid may be located within the housing. The increased amount of cooling liquid may further result from any suitable event, such as an additional amount of cooling liquid flow into housing 230 before spring 306 is able to push check valve seat 304 in contact with opening 410. In this situation, compression bladder 302 may compress under the increase in pressure on the compression bladder to enable fluid displacement of the additional cooling liquid when quick disconnect release is made.

In previous liquid cooling systems, a check valve is mounted in a rigid enclosure and a quick disconnect plunger may attempt to displace liquid within the assembly, such as the cold supply manifold or the hot return manifold. In this situation of previous liquid cooling systems, the check valve is in a closed state and does not provide a place for the non-compressible fluid to go. Without the non-compressible fluid being displaced within the assembly, the entire system may become hydro-locked. Based on inline check valve 200 being placed within system 100 of FIG. 1, compression bladder 302 may allow for the compression, fluid displacement from a quick disconnect component 120 in FIG. 1, and elimination of a hydro-lock within system 100 of FIG. 1.

FIG. 5 shows a check valve component 500 including compression bladder 302 and check valve seat 304 according to at least one embodiment of the present disclosure. Compression bladder 302 includes multiple sections 510 that extend away from the center portion of the compression bladder. Sections 510 may form any suitable shape to create channels 512 between the sections. In an example, sections 510 may form a cross-section shape of a “+sign” as illustrated in FIG. 5. Check valve seat 304 includes a taper section 520, which in turn may connect with a washer 522. Check valve component 500 may include additional features without varying from the scope of this disclosure.

In an example, both taper section 520 and washer 522 may include extension portions 530, which in turn may be positioned around the outer edges of taper section and washer. In certain examples, the position and size of extension portions 530 may create fluid channels 532 along check valve seat 304. As illustrated in FIG. 5, washer 522 may be located between compression bladder 302 and check valve seat 304. In an example, compression bladder 302, washer 522, and check valve seat 304 may be adhered together as an assembly. The connection of compression bladder 302, washer 522, and check valve seat 304 may be done in any suitable manner, such as with an adhesive, welding by a plastic spin welding process, or the like. In an example, the spin welding process may create friction between the ethylene propylene diene monomer (EPDM) parts and melt the plastic interface and bonds the parts. In certain examples, channels 512 of compression bladder 302 and channels 532 of check valve seat 304 may allow coolant to flow around the compression bladder and the check valve seat.

Taper section 520 of check valve seat 304 may be any suitable pliable material, such as EPDM to enable the taper section to seal a housing of an inline check valve, such as housing 230 of pressure relieving check valve 204 in FIG. 2. Based on taper section 520 valve seat being pliable, washer 522 is metal so that a spring with a housing of an inline check valve, such as spring 306 in housing 230 of pressure relieving check valve 204 in FIG. 2, does not compress or cut into taper section. One geometry of compression bladder 302 and check valve seat 304 with respective channels 512 and 532 have been described and shown. However, other geometries of compression bladder 302 and check valve seat 304 may be utilized to allow for flow channels within a housing of an inline check valve, such as spring 306 in housing 230 of pressure relieving check valve 204 in FIG. 2, without varying from the scope of this disclosure.

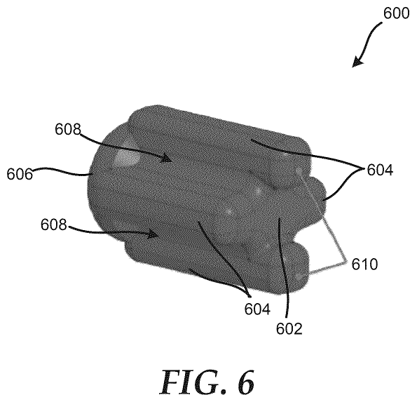

In an alternate implementation, compression bladder 302 may free float within spring 306. In this implementation, check valve seat 304 and spring 306 may be separate from compressible bladder 302. Based on compression bladder 302 free floating within housing 230, the compression bladder may float to the fluid exit end of the housing and inhibit fluid flow. In this situation, compression bladder 512 may include multiple protrusions or feet, such as feet 610 in FIG. 6. These protrusions/feet may contact the wall of housing 230 next to the fluid exit allowing fluid to flow through the exit opening.

FIG. 6 illustrates a perspective view of a compression bladder 600 for an inline check valve according to at least one embodiment of the present disclosure. Compression bladder 600 may be substantially similar to compression bladder 302 in FIGS. 3-5. Compression bladder 600 includes a main portion 602, extension sections 604, and a front portion 606. Extension sections 604 may form channels 608 along compression bladder 600. One or more extension sections 604 include a foot 610. In an example, each foot 610 may extend a predetermined length beyond the corresponding extension section 604. This length of each foot 610 may provide a gap between compression bladder 600 and a housing of an inline check valve, such as housing 230 of pressure relieving check valve 204 in FIG. 2. Compression bladder 600 may include additional components or features without varying from the scope of this disclosure.

In an example, compression bladder 600 may be a sealed elastomeric chamber. Compression bladder 600 may be formed in any suitable process, such as a blow molding process or the like. In certain examples, the blow molding process may leave a hole in front portion 606 where air is injected into the parison to inflate the heated material and press the material into the mold cavities. In these situations, the inflation hole may be located at end of front portion 606 where compression bladder 600 interfaces with a washer and check valve seat, such as washer 522 and check valve seat 302 in FIG. 5.

In an example, a cooling loop, such as the cooling loop in FIG. 1, may have a system pressure of 25-35 PSI. In this example, compression bladder 600 may be assembled at any pressure level, such as atmospheric pressure. This assembly pressure may be used to bond compression bladder assembly 600 at normal environmental pressure.

When compression bladder 600, which is air-filled, may be utilized within a chamber between a quick disconnect (QD) plug and a check valve, such as return side connector 122 and inline check valve 124 of FIG. 1. Compression bladder 600 may enable a compressible volume within inline check valve that may become smaller as coolant is forced back into the chamber, such as housing 230 of FIG. 2, when the QD is plugged into the rack coolant manifold. In certain examples, compression bladder 600 may be designed with an internal volume that when compressed to a particular pressure, such as 35 PSI, may still have a remaining internal volume to consume a fluid displacement generated when connecting a QD to a cooling manifold within a server rack. The compression of bladder 600 caused by coolant displacement and increased pressure within an inline check valve may enable more volume for the displaced fluid.

In an example, the behavior of sealed compression bladder 600 may follow the rules established by the Ideal Gas Law. In this situation, compression bladder 600 should have room to grow to account for temperature changes during normal liquid cooling system operation. In an example, the growth or reduction in the volume of compression bladder 600 may be linear with the Kelvin temperature change.

The nominal pressure of compression bladder 600 may be any suitable pressure and in response to the pressure doubling, the compression bladder may collapse enough to allow for dripless fitting mating. In a non-limiting example, the pressure of compression bladder 600 may be 13 PSI, and upon the pressure reaching 26 PSI, the bladder may collapse to allow liquid displacement. In an example, as pressure doubles for compression bladder 600 the volume of the compression bladder is halved. In certain examples, the volume of compression bladder 600 may increase linearly as the temperature of a coolant fluid of a liquid cooling assembly increases. Additionally, the volume of compression bladder 600 may be substantially halved when the pressure within an inline check valve, such as pressure relieving check valve 204 of FIG. 2 is doubled. In this situation, the volume reduction of compression bladder 600 may be enough to accommodate the reverse fluid flow of a dripless QD fitting.

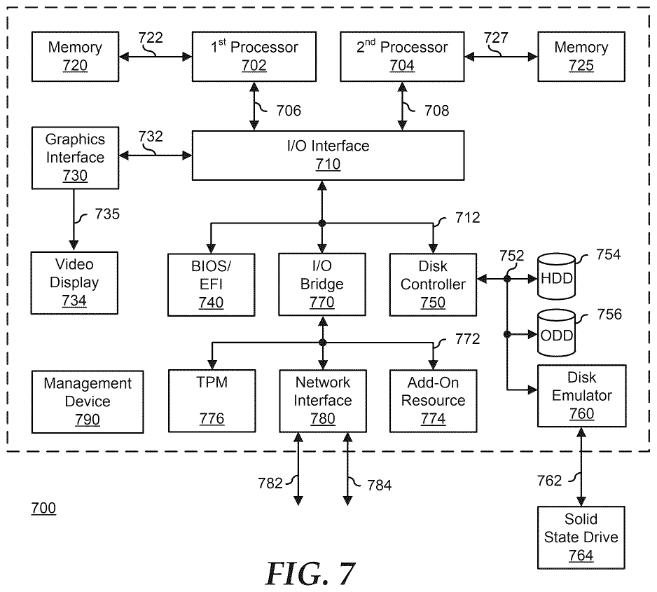

FIG. 7 shows a generalized embodiment of an information handling system 700 according to an embodiment of the present disclosure. Information handling system 700 may be substantially similar to information handling systems or servers 102 of FIG. 1. Information handling system 700 can include devices or modules that embody one or more of the devices or modules described below and operates to perform one or more of the methods described below. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756, a disk emulator 760 connected to an external solid state drive (SSD) 764, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756, disk emulator 760, SSD 764, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708. Memory 720 is connected to processor 702 via a memory interface 722. Memory 725 is connected to processor 704 via a memory interface 727. Graphics interface 730 is connected to I/O interface 710 via a graphics interface 732 and provides a video display output 736 to a video display 734. In a particular embodiment, information handling system 700 includes separate memories that are dedicated to each of processors 702 and 704 via separate memory interfaces. An example of memories 720 and 730 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 4394 (Firewire) interface, a proprietary interface, or a combination thereof. Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712 or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof. Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700.

Management device 790 can operate off of a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An inline check valve for an information handling system, the inline check valve comprising:
a housing configured to enable a cooling liquid to flow in first and second directions through the inline check valve;
a check valve seat located within the housing, the check valve seat to enable the cooling liquid to flow only in the first direction through the housing, wherein the check valve seat is biased toward a first end of the housing; and
a compression bladder located within the housing, the compression bladder configured to collapse to enable fluid displacement within the housing.

2. The inline check valve of claim 1, further comprising a spring in physical communication with the check valve seat, wherein the spring exerts a first force against the check valve seat to bias the check valve seat toward the first end of the housing.

3. The inline check valve of claim 2, wherein the flow of the cooling liquid in the first direction exerts a second force against the check valve seat, when the second force is greater than the first force, the check valve seat is pushed away from the first end of the housing to enable the cooling liquid to flow through the inline check valve in the first direction.

4. The inline check valve of claim 1, wherein the check valve seat includes: a taper portion including a first plurality of channels to enable the flow of the cooling liquid within the housing.

5. The inline check valve of claim 4, further comprising: a metal washer connected to the taper portion of the check valve seat, the metal washer includes a second plurality of channels to enable the flow of the cooling liquid within the housing.

6. The inline check valve of claim 5, wherein the first and second channels are aligned.

7. The inline check valve of claim 4, when the flow of the cooling liquid stops in the housing, the taper portion is placed in physical communication with an opening of the housing to prevent a second flow of the cooling liquid in the second direction through the housing.

1. The inline check valve of claim 1, wherein the compression bladder includes:
a main portion; and
a plurality of extension sections that extend from the main portion, wherein channels are located between the extension sections to enable the flow of the cooling liquid within the housing.

9. A system comprising:
an information handling system;
a liquid cooling supply manifold to supply a cooling liquid to the information handling system; and
an inline check valve coupled to the liquid cooling supply manifold, the inline check valve including:
a housing configured to enable the cooling liquid to flow in first and second directions through the inline check valve;
a check valve seat located within the housing, the check valve seat to enable the cooling liquid to flow only in the first direction through the housing, wherein the check valve seat is biased toward a first end of the housing; and
a compression bladder located within the housing, the compression bladder configured to collapse to enable fluid displacement within the housing.

10. The system of claim 9, wherein the inline check valve further comprises a spring in physical communication with the check valve seat, wherein the spring exerts a first force against the check valve seat to bias the check valve seat toward the first end of the housing.

11. The system of claim 10, wherein the flow of the cooling liquid in the first direction exerts a second force against the check valve seat, when the second force is greater than the first force, the check valve seat is pushed away from the first end of the housing to enable the cooling liquid to flow through the inline check valve in the first direction.

12. The system of claim 9, wherein the check valve seat includes: a taper portion including a first plurality of channels to enable the flow of the cooling liquid within the housing.

2. The system of claim 12, wherein the inline check valve further comprises: a metal washer connected to the taper portion of the check valve seat, the metal washer includes a second plurality of channels to enable the flow of the cooling liquid within the housing.

14. The system of claim 13, wherein the first and second channels are aligned.

15. The system of claim 12, when the flow of the cooling liquid stops in the housing, the taper portion is placed in physical communication with an opening of the housing to prevent a second flow of the cooling liquid in the second direction through the housing.

3. The system of claim 9, wherein the compression bladder includes:
a main portion; and
a plurality of extension sections that extend from the main portion, wherein channels are located between the extension sections to enable the flow of the cooling liquid within the housing.

4. A system comprising:
an information handling system;
a liquid cooling supply manifold to supply a cooling liquid to the information handling system;
a return manifold to receive hot liquid from the information handling system; and
an inline check valve coupled to the liquid cooling supply manifold, the inline check valve including:
a housing configured to enable the cooling liquid to flow in first and second directions through the inline check valve;
a check valve seat located within the housing, the check valve seat to enable the cooling liquid to flow only in the first direction through the housing, wherein the check valve seat is biased toward a first end of the housing; and
a compression bladder located within the housing, the compression bladder collapsible to enable fluid displacement within the housing.

18. The system of claim 17, wherein the inline check valve further comprises a spring in physical communication with the check valve seat, wherein the spring exerts a first force against the check valve seat to bias the check valve seat toward the first end of the housing.

19. The system of claim 18, wherein the flow of the cooling liquid in the first direction exerts a second force against the check valve seat, when the second force is greater than the first force, the check valve seat is pushed away from the first end of the housing to enable the cooling liquid to flow through the inline check valve in the first direction.

20. The system of claim 18, wherein the inline check valve further comprises: a metal washer connected between the check valve seat and the spring, the metal washer includes a plurality of channels to enable the flow of the cooling liquid within the housing.
